(19) United States
(12) Patent Application Publication
(10) Pub. No.: US 2020/0378764 A1
(43) Pub. Date: Dec. 3, 2020

(54) SENSOR UNIT, ELECTRONIC APPARATUS, AND VEHICLE

(71) Applicant: Seiko Epson Corporation, Tokyo (JP)

(72) Inventors: Ryuji KIHARA, Matsumoto (JP); Kentaro YODA, Chino (JP)

(21) Appl. No.: 16/886,959

(22) Filed: May 29, 2020

(30) Foreign Application Priority Data
May 31, 2019 (JP) 2019-102982

(51) Int. Cl. G01C 19/5783; B81B 7/00; G01D 11/24; G01P 1/02

(52) U.S. Cl. CPC G01C 19/5783; B81B 7/0016; B81B 7/0058; B81B 2201/0235; G01P 1/023; B81B 2201/025; G01D 11/245

(57) ABSTRACT

A sensor unit includes: a sensor module having an inertial sensor installed therein and having a bottom wall and a sidewall; abase where the sensor module is provided; a first bonding member bonding the base and the sidewall together; and a second bonding member bonding the base and the bottom wall together. The sensor module is a polygon as viewed in a plan view of the bottom wall. The base and the sidewall are bonded together via the first bonding member at a part of at least one side of the polygon except corners.

The present application is based on, and claims priority from, JP Application Serial Number 2019-102982, filed May 31, 2019, the disclosure of which is hereby incorporated by reference herein in its entirety.

### BACKGROUND

### 1. Technical Field

The present disclosure relates to a sensor unit, an electronic apparatus, and a vehicle.

### 2. Related Art

For example, in a sensor unit described in JP-A-2016-118421, a sensor module with an inertial sensor installed therein is fixed to an outer case with a screw. Also, a flexible bonding member is provided between the outer case and the sensor module. The outer case and the sensor module are bonded together via this bonding member.

However, in the sensor unit with such a configuration, the sensor module is fixed to the outer case with the screw and therefore noise vibration generated in the outer case tends to be transmitted to the inertial sensor via the screw. Meanwhile, when the screw is eliminated to make the noise vibration less likely to be transmitted to the inertial sensor and the sensor module and the outer case are bonded together only via the bonding member, impact resistance or performance against noise in an in-plane direction, that is, in a direction perpendicular to the screw, drops.

### SUMMARY

A sensor unit according to an aspect of the present disclosure includes: a sensor module having an inertial sensor installed therein and having a bottom wall and a sidewall; a base where the sensor module is provided; a first bonding member bonding the base and the sidewall together; and a second bonding member bonding the base and the bottom wall together. The sensor module is a polygon as viewed in a plan view of the bottom wall. The base and the sidewall are bonded together via the first bonding member at a part of at least one side of the polygon except corners.

### BRIEF DESCRIPTION OF THE DRAWINGS

FIG. 1 is a perspective view of a sensor unit according to a first embodiment of the present disclosure.

FIG. 2 is an exploded perspective view of the sensor unit shown in FIG. 1.

FIG. 3 is an exploded perspective view of a sensor module.

FIG. 4 is a perspective view of a substrate forming the sensor module shown in FIG. 3.

FIG. 5 is a cross-sectional view of the sensor module.

FIG. 6 is a top view of the sensor unit.

FIG. 7 is a graph showing a detection signal of an acceleration along a Z-axis when vibration along the Z-axis is applied to the sensor unit shown in FIG. 1.

FIG. 8 is a histogram of the detection signal shown in FIG. 7.

FIG. 9 is a top view showing a sensor unit according to a comparative example.

FIG. 10 is a graph showing a detection signal of an acceleration along the Z-axis when vibration along the Z-axis is applied to the sensor unit shown in FIG. 9.

FIG. 11 is a histogram of the detection signal shown in FIG. 10.

FIG. 12 is a graph showing a detection signal of an acceleration along a Y-axis and an X-axis when vibration along the Z-axis is applied to the sensor unit shown in FIG. 1.

FIG. 13 is a histogram of the detection signal shown in FIG. 12.

FIG. 14 is a graph showing a detection signal of an acceleration along the Y-axis and the X-axis when vibration along the Z-axis is applied to the sensor unit shown in FIG. 9.

FIG. 15 is a histogram of the detection signal shown in FIG. 14.

FIG. 16 is a cross-sectional view of the sensor unit.

FIG. 17 is a cross-sectional view showing a sensor module according to a second embodiment.

FIG. 18 is a perspective view showing a smartphone according to a third embodiment.

FIG. 19 is a block diagram showing an overall system of a vehicle positioning device according to a fourth embodiment.

FIG. 20 shows an operation of the vehicle positioning device shown in FIG. 19.

FIG. 21 is a perspective view showing a vehicle according to a fifth embodiment.

### DESCRIPTION OF EXEMPLARY EMBODIMENTS

A sensor unit, an electronic apparatus, and a vehicle according to the present disclosure will now be described in detail, based on embodiments shown in the accompanying drawings.

### First Embodiment

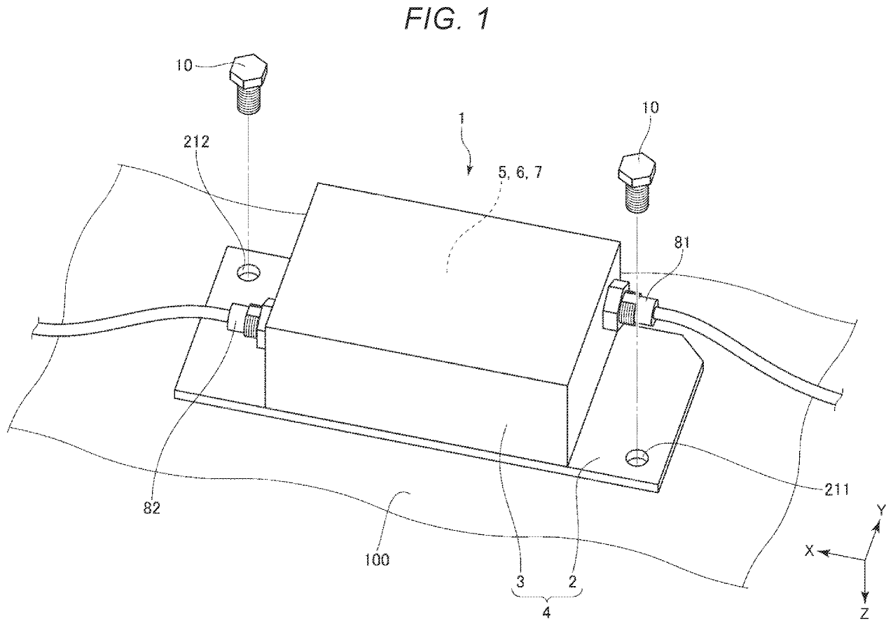

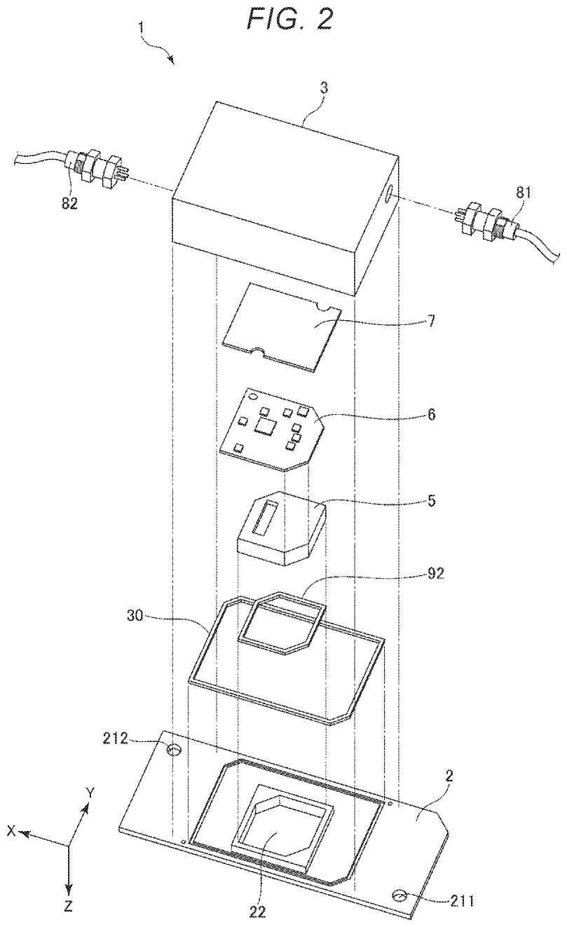

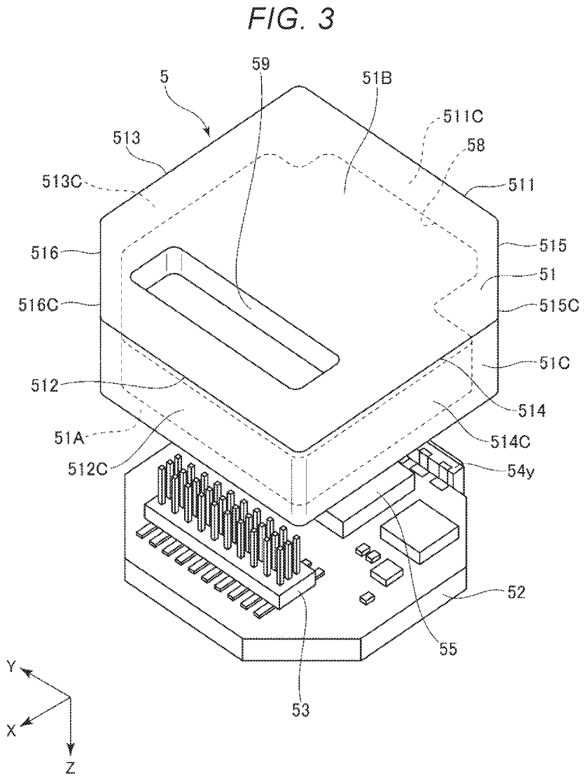

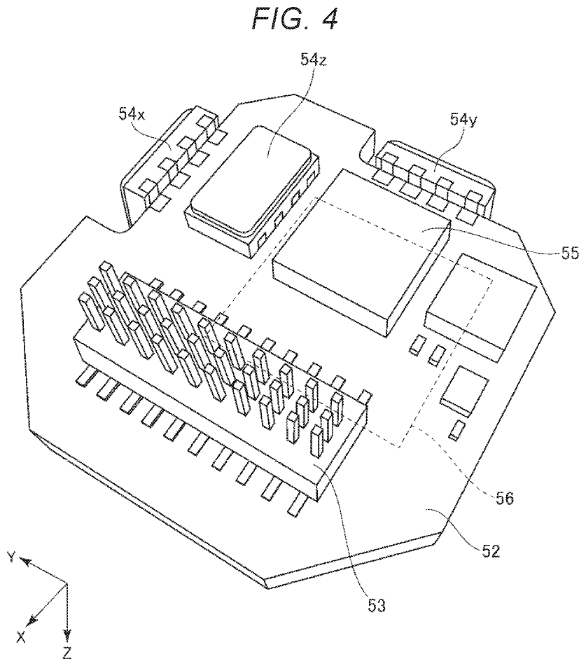

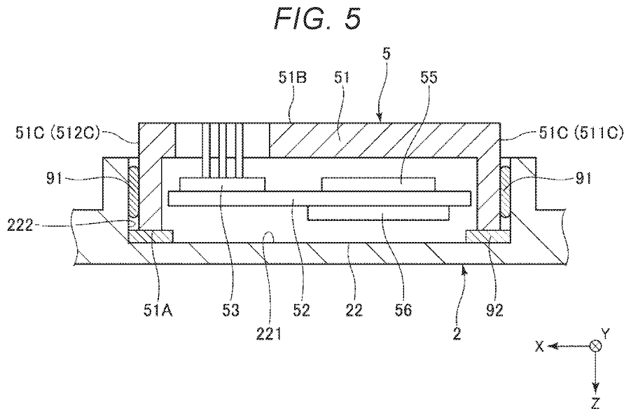

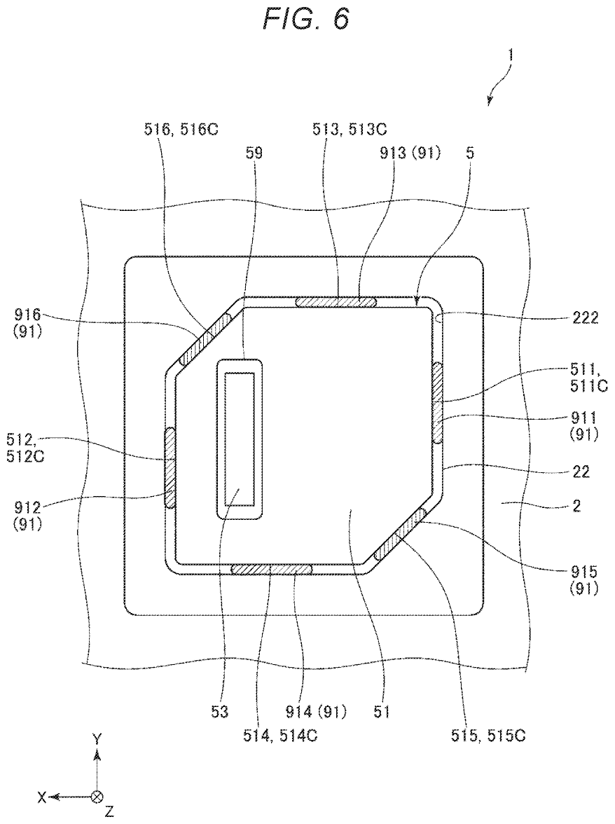

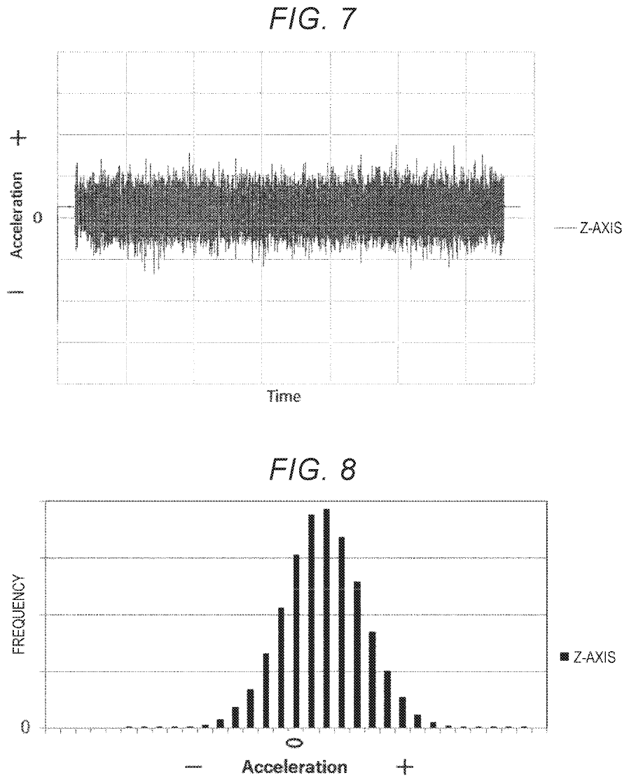

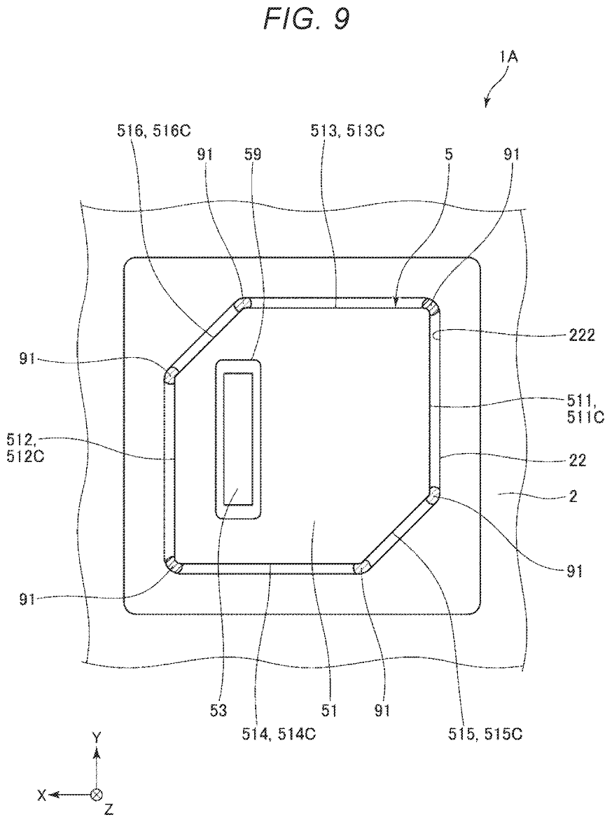

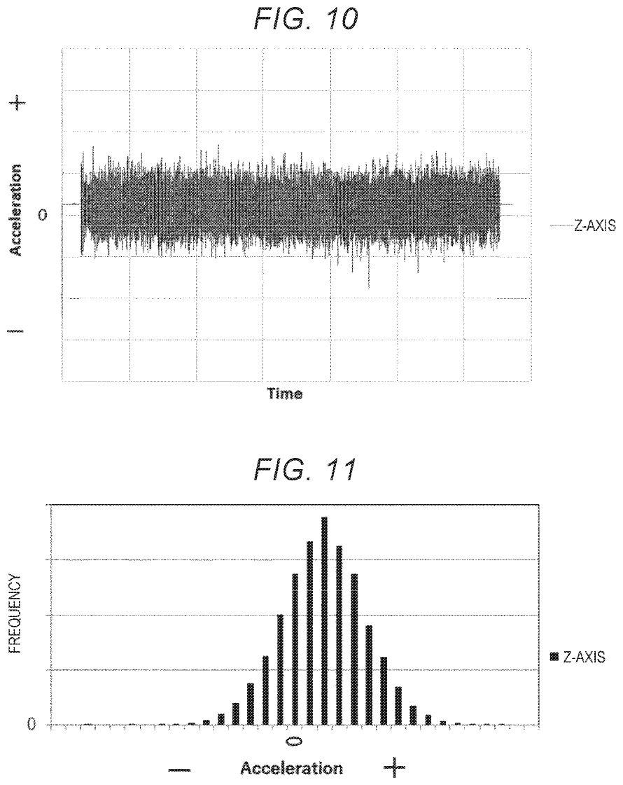

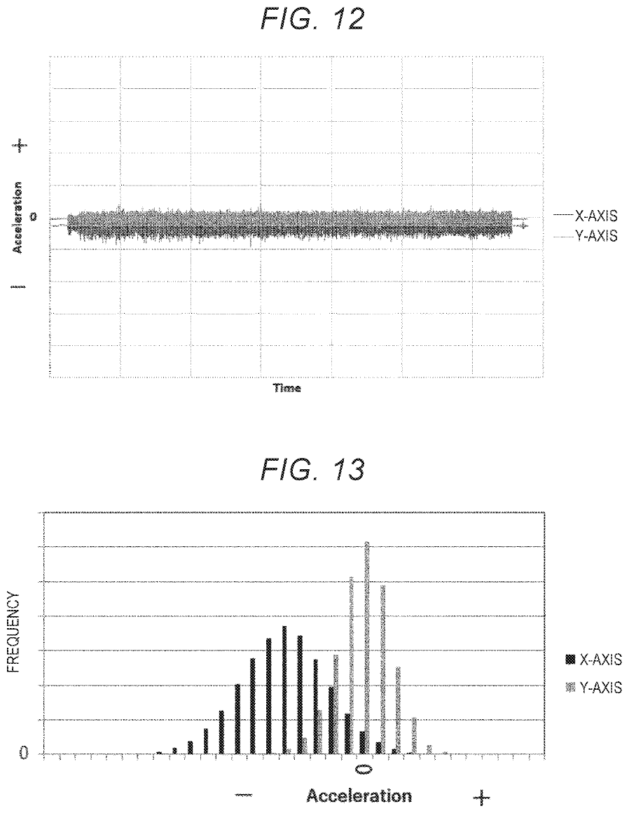

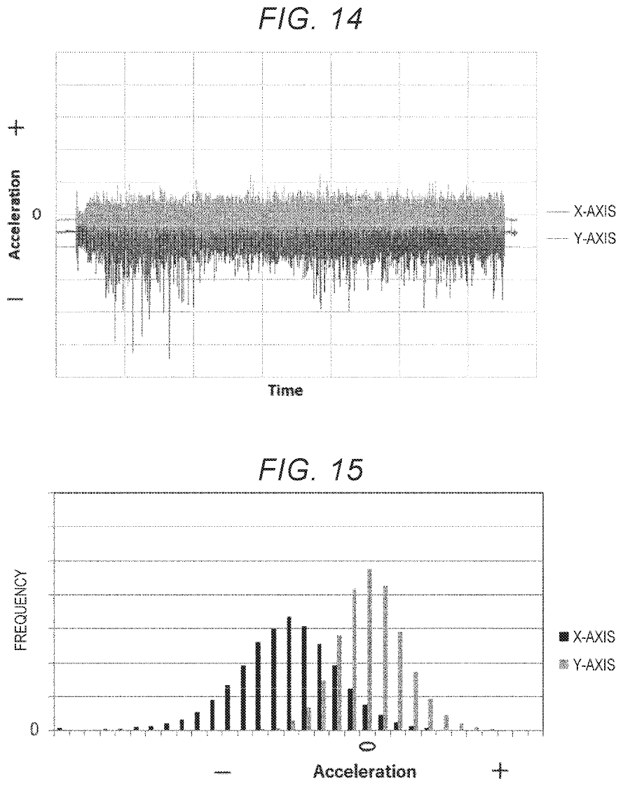

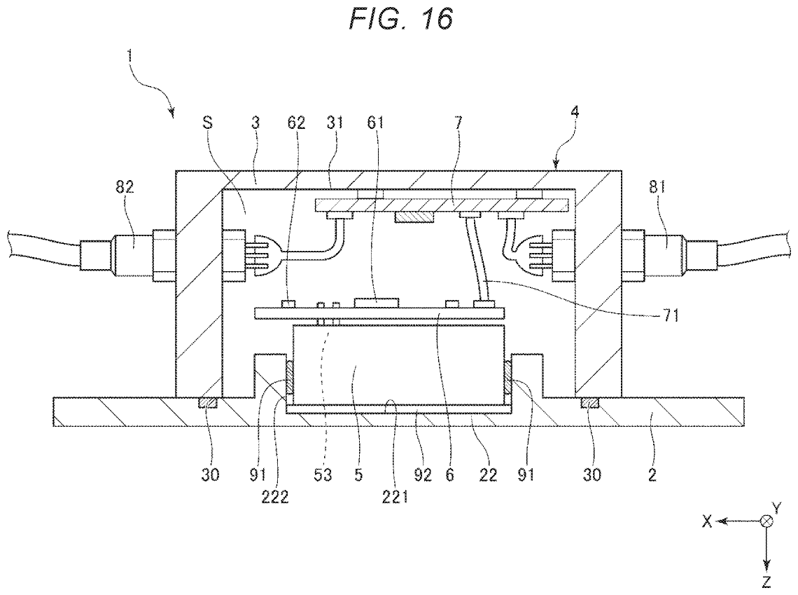

FIG. 1 is a perspective view of a sensor unit according to a first embodiment of the present disclosure. FIG. 2 is an exploded perspective view of the sensor unit shown in FIG. 1. FIG. 3 is an exploded perspective view of a sensor module. FIG. 4 is a perspective view of a substrate forming the sensor module shown in FIG. 3. FIG. 5 is a cross-sectional view of the sensor module. FIG. 6 is a top view of the sensor unit. FIG. 7 is a graph showing a detection signal of an acceleration along a Z-axis when vibration along the Z-axis is applied to the sensor unit shown in FIG. 1. FIG. 8 is a histogram of the detection signal shown in FIG. 7. FIG. 9 is a top view showing a sensor unit according to a comparative example. FIG. 10 is a graph showing a detection signal of an acceleration along the Z-axis when vibration along the Z-axis is applied to the sensor unit shown in FIG. 9. FIG. 11 is a histogram of the detection signal shown in FIG. 10. FIG. 12 is a graph showing a detection signal of an acceleration along a Y-axis and an X-axis when vibration along the Z-axis is applied to the sensor unit shown in FIG. 1. FIG. 13 is a histogram of the detection signal shown in FIG. 12. FIG. 14 is a graph showing a detection signal of an acceleration along the Y-axis and the X-axis when vibration along the Z-axis is applied to the sensor unit shown in FIG. 9. FIG. 15 is a histogram of the detection signal shown in FIG. 14. FIG. 16 is a cross-sectional view of the sensor unit.

In the drawings except FIGS. 7, 8, 10 to 15, for the sake of convenience of the description, the X-axis, the Y-axis, and the Z-axis are shown as three axes orthogonal to each other. In the description below, the negative side along the Z-axis is also referred to as “up” and the positive side is also referred to as “down”. When a component is viewed in a plan view from a direction along the Z-axis, it is also referred to simply as being “viewed in a plan view”.

A sensor unit 1 shown in FIG. 1 is an inertial measuring device detecting an attitude or behavior of a vehicle such as an automobile, agricultural machine, construction machine, robot, and drone. The sensor unit 1 can function as a six-axis motion sensor having an angular velocity sensor detecting angular velocities on three axes and an acceleration sensor for three axes, as inertial sensors, or can function as a three-axis motion sensor having an acceleration sensor detecting accelerations on three axes. The sensor unit 1 is a rectangular-parallelepiped having a rectangular shape as viewed in a plan view and has a size approximately 100 mm long on the longer side along the X-axis, approximately 40 mm long on the shorter side along the Y-axis orthogonal to the X-axis, and approximately 30 mm thick along the Z-axis. However, the size of the sensor unit 1 is not particularly limited.

Such a sensor unit 1 has: a container 4 including a base 2 and a recessed lid 3 fixed to the base 2; a sensor module 5, a control circuit board 6, and a I/F (interface) circuit board 7 accommodated in the container 4; and connectors 81 and 82 fixed to the lid 3 and electrically coupled to the I/F circuit board 7.

The base 2 has a plate-like shape having a thickness along the Z-axis and is rectangular as viewed in a plan view, with its longitudinal direction laid along the X-axis. At both ends in the longitudinal direction of the base 2, two diagonally opposite screw holes 211 and 212 are formed. The sensor unit 1 is fixed to a target object 100 by having fixing screws 10 inserted and tightened in the screw holes 211 and 212 and is used in this state. As shown in FIG. 2, a closed-bottom recess 22 opening at an upper side is provided at a center part in the longitudinal direction of the base 2. The sensor module 5 is fitted in the recess 22.

Such a base 2 is formed of, for example, aluminum. This makes the base 2 hard enough. However, the material forming the base 2 is not particularly limited to aluminum. Other metal materials such as zinc and stainless, various ceramics, various resin materials, a composite material of a metal material and a resin material or the like can be used.

As shown in FIG. 3, the sensor module 5 has a case 51 and a substrate 52. The case 51 is a member supporting the substrate 52 and has a shape that can be inserted in the recess 22 formed in the base 2. Such a case 51 has a bottom wall 51A as its lower surface, a top wall 51B as its upper surface located opposite to the bottom wall 51A along the Z-axis, and a sidewall 51C coupling the bottom wall 51A and the top wall 51B together. Also, a recess 58 opening to the bottom wall 51A, and an opening 59 formed of a penetration hole penetrating the top wall 51B and the bottom surface of the recess 58, are formed in the case 51. The substrate 52 is provided inside the recess 58.

The case 51 is a polygon as viewed in a plan view from a direction along the Z-axis. That is, each of the bottom wall 51A and the top wall 51B is polygonal. The case 51 in this embodiment is hexagonal as viewed in a plan view from a direction along the Z-axis. The basic shape of the case 51 is rectangular, particularly square, and a set of opposite corners are cut obliquely by 45 degrees. Therefore, the case 51 has a pair of sides 511 and 512 extending along the Y-axis and facing in a direction along the X-axis, a pair of sides 513 and 514 extending along the X-axis and facing in a direction along the Y-axis, a side 515 coupling the sides 511 and 514 together and inclined by 45 degrees from the X-axis and the Y-axis, and a side 516 coupling the sides 512 and 513 together and inclined by 45 degrees from the X-axis and the Y-axis. The sides 515 and 516 are shorter than any of the sides 511, 512, 513 and 514.

The sidewall 51C has a sidewall 511C coupled to the side 511, a sidewall 512C coupled to the side 512, a sidewall 513C coupled to the side 513, a sidewall 514C coupled to the side 514, a sidewall 515C coupled to the side 515, and a sidewall 516C coupled to the side 516. That is, the sidewalls 511C, 512C, 513C, 514C, 515C and 516C exist at a certain part of the sides 511, 512, 513, 514, 515 and 516, respectively.

However, the shape of the case 51 as viewed in a plan view is not particularly limited, provided that it is a polygon, that is, an equilateral polygon or any other polygon. The number of sides of the polygon is not particularly limited, either. The “polygon” may be, for example, a shape having at least one corner rounded or chamfered, or a shape having at least one side curved instead of straight, in addition to shapes geometrically defined as polygons.

As shown in FIG. 4, a connector 53, an angular velocity sensor 54z detecting an angular velocity about the Z-axis, and an acceleration sensor 55 detecting an acceleration along each of the X-axis, the Y-axis, and the Z-axis, and the like, are installed at the upper surface of the substrate 52. The connector 53 is exposed outside the case 51 via the opening 59. Also, an angular velocity sensor 54x detecting an angular velocity about the X-axis and an angular velocity sensor 54y detecting an angular velocity about the Y-axis are installed at lateral sides of the substrate 52. The configurations of the angular velocity sensors 54x, 54y and 54z and the acceleration sensor 55 as inertial sensors are not particularly limited, provided that these sensors can achieve their respective functions. In this embodiment, each of the angular velocity sensors 54x, 54y and 54z has a configuration utilizing a quartz crystal oscillator, and the acceleration sensor 55 has a configuration utilizing a silicon MEMS having an interdigital electrode structure.

A control IC 56 is installed at the lower surface of the substrate 52. The control IC 56 is an MCU (microcontroller unit) and controls each part of the sensor module 5. In a storage unit provided in the control IC 56, a program prescribing an order and content for detecting the acceleration and angular velocity, a program for digitizing detection data and incorporating the digitized detection data into packet data, and accompanying data or the like are stored. Also, a plurality of other electronic components are installed at the substrate 52 according to need.

The sensor module 5 configured as described above is inserted from the bottom wall 51A side into the recess 22 formed in the base 2, and the part on the top wall 51B side protrudes and is exposed from the recess 22, as shown in FIG. 5. The sensor module 5 is bonded to the base 2 via a first bonding member 91 and a second bonding member 92.

The second bonding member 92 is provided between the bottom wall 51A of the sensor module 5 and a bottom surface 221 of the recess 22 and bonds the bottom wall 51A and the bottom surface 221 together. As shown in FIG. 2, the second bonding member 92 is formed of a seal member in a frame-like shape, particularly a loop-like shape, corresponding to the shape of the bottom wall 51A of the sensor module 5 as viewed in a plan view, and the lateral surface of the seal member is in contact with a lateral surface 222 of the recess 22. This can increase the bonding strength between the sensor module 5 and the base 2. The lateral surface 222 is loop-shaped as viewed in a plan view in FIG. 6.

The second bonding member 92 has a lower elastic modulus than the base 2. That is, the second bonding member 92 is flexible and softer than the base 2. The second bonding member 92, which is made soft in this way, can absorb and damp noise vibration transmitted from the base 2 and thus makes the noise vibration less likely to be transmitted to the sensor module 5. Therefore, a drop in the detection property of the angular velocity sensors 54x, 54y and 54z and the acceleration sensor 55 can be effectively restrained.

The material forming the second bonding member 92 is not particularly limited. For example, various rubber materials such as natural rubber, isoprene rubber, butadiene rubber, styrene-butadiene rubber, nitrile rubber, chloroprene rubber, butyl rubber, acrylic rubber, ethylene-propylene rubber, hydrin rubber, urethane rubber, silicone rubber, and fluorine rubber, and various thermoplastic elastomers such as styrene-based, polyolefin-based, polyvinyl chloride-based, polyurethane-based, polyester-based, polyamide-based, polybutadiene-based, trans-polyisoprene-based, fluorine rubber-based, and chlorinated polyethylene-based thermoplastic elastomers can be employed. Of these, one type or a mixture of two or more types can be used. In this embodiment, the second bonding member 92 is formed of silicone rubber.

Meanwhile, the first bonding member 91 is provided between the sidewall 51C of the sensor module 5 and the lateral surface 222 of the recess 22 and bonds the sidewall 51C and the lateral surface 222 together. More specifically, the first bonding member 91 is located between a site excluding the corners of the polygon, of the sidewalls 511C, 512C, 513C, 514C, 515C and 516C, and the lateral surface 222, and bonds these together. The first bonding member 91 has a lower elastic modulus than the base 2. That is, the first bonding member 91 is flexible and softer than the base 2. The first bonding member 91, which is made soft in this way, can absorb and damp noise vibration transmitted from the base 2 and thus makes the noise vibration less likely to be transmitted to the sensor module 5. Therefore, a drop in the detection property of the angular velocity sensors 54x, 54y and 54z and the acceleration sensor 55 can be effectively restrained.

As shown in FIG. 6, the first bonding member 91 is provided, not in contact with the corners of the case 51. In this case, the first bonding member 91 bonds the sidewall 51C and the lateral surface 222 of the recess 22 together, at a center part of the respective sides 511 to 516. More specifically, the first bonding member 91 has a bonding member 911 bonding a center part excluding the two ends in the direction of width of the sidewall 511C and the lateral surface 222, a bonding member 912 bonding a center part excluding the two ends in the direction of width of the sidewall 512C and the lateral surface 222, a bonding member 913 bonding a center part excluding the two ends in the direction of width of the sidewall 513C and the lateral surface 222, a bonding member 914 bonding a center part excluding the two ends in the direction of width of the sidewall 514C and the lateral surface 222, a bonding member 915 bonding a center part excluding the two ends in the direction of width of the sidewall 515C and the lateral surface 222, and a bonding member 916 bonding a center part excluding the two ends in the direction of width of the sidewall 516C and the lateral surface 222. The “two ends in the direction of width of the sidewall 51C” are the same as the two ends in the longitudinal direction of the sidewall 51C as viewed in a plan view in FIG. 6 and refer to the corners of the polygon, which is the shape of the case 51 as viewed in a plan view, and the vicinities of the corners.

Since the sidewall 51C and the lateral surface 222 are bonded together at the sites excluding the corners of the respective sides 511 to 516, instead of over the entire circumference of the case 51 or only at the corners of the case 51 as in a comparative example shown in FIG. 9, the sensor unit 1 is less likely to be affected by noise vibration and can effectively restrain a drop in detection property. The reason for this will now be confirmed, using experimental data.

Noise vibration along the Z-axis is applied to the sensor unit 1 according to this embodiment. FIG. 7 shows a detection signal of an acceleration along the Z-axis outputted from the acceleration sensor 55, based on this noise vibration. FIG. 8 shows an acceleration histogram prepared from the detection signal. Meanwhile, noise vibration along the Z-axis similar to the above is applied to a sensor unit 1A according to a comparative example where the sidewall 51C and the lateral surface 222 are bonded together only at the corners of the case 51, as shown in FIG. 9. FIG. 10 shows a detection signal of an acceleration along the Z-axis outputted from the acceleration sensor 55, based on this noise vibration. FIG. 11 shows an acceleration histogram prepared from the detection signal. As can be seen from FIGS. 7, 8, 10, and 11, there is no large difference in noise sensitivity along the Z-axis between the sensor units 1 and 1A.

Noise vibration along the Z-axis is applied to the sensor unit 1 according to this embodiment. FIG. 12 shows a detection signal of an acceleration along the X-axis and the Y-axis outputted from the acceleration sensor 55, based on this noise vibration. FIG. 13 shows an acceleration histogram prepared from the detection signal. Meanwhile, noise vibration along the Z-axis similar to the above is applied to the sensor unit 1A. FIG. 14 shows a detection signal of an acceleration along the X-axis and the Y-axis outputted from the acceleration sensor 55, based on this noise vibration. FIG. 15 shows an acceleration histogram prepared from the detection signal. As can be seen from FIGS. 12 to 15, with respect to noise characteristics along the X-axis and the Y-axis, the range between the maximum value and the minimum value of the detected acceleration is smaller for the sensor unit 1 than for the sensor unit 1A and therefore the sensor unit 1 has a lower noise sensitivity. That is, it can be understood that the sensor unit 1 is less likely to be affected by noise vibration than the sensor unit 1A and can restrain a drop in detection property more effectively.

The material forming the first bonding member 91 is not particularly limited. For example, various rubber materials such as natural rubber, isoprene rubber, butadiene rubber, styrene-butadiene rubber, nitrile rubber, chloroprene rubber, butyl rubber, acrylic rubber, ethylene-propylene rubber, hydrin rubber, urethane rubber, silicone rubber, and fluorine rubber, and various thermoplastic elastomers such as styrene-based, polyolefin-based, polyvinyl chloride-based, polyurethane-based, polyester-based, polyamide-based, polybutadiene-based, trans-polyisoprene-based, fluorine rubber-based, and chlorinated polyethylene-based thermoplastic elastomers can be employed. Of these, one type or a mixture of two or more types can be used. In this embodiment, the first bonding member 91 is formed of silicone rubber.

The elastic modulus of the first and second bonding members 91 and 92 is not particularly limited but is preferably, for example, approximately 1.0 MPa or higher and 2.0 MPa or lower. This makes the first and second bonding members 91 and 92 sufficiently soft and can achieve the foregoing effect more effectively. Preferably, the first and second bonding members 91 and 92 have different elastic moduli from each other. This enables the first bonding member 91 and the second bonding member 92 to effectively absorb and damp different frequency ranges of noise vibration from each other and therefore enables the first and second bonding members 91 and 92 together to absorb and damp a broader frequency range of noise vibration. In this embodiment, the elastic modulus of the first bonding member 91 is approximately 1.7 MPa and the elastic modulus of the second bonding member 92 is approximately 1.58 MPa.

As shown in FIG. 16, the control circuit board 6 is provided above the sensor module 5, that is, between the top part of the lid 3 and the sensor module 5. The control circuit board 6 is coupled to the connector 53 of the sensor module 5. At such a control circuit board 6, a control circuit element 61 and a plurality of electronic components 62 are installed. The control circuit element 61 is, for example, an MCU (microcontroller unit). A storage unit including a non-volatile memory, and an A/D converter, are built in the control circuit element 61. The control circuit element 61 can control each part of the sensor unit 1.

The I/F circuit board 7 is provided above the control circuit board 6, that is, between the top part of the lid 3 and the control circuit board 6. The I/F circuit board 7 is electrically coupled to the control circuit board 6 via a coupling wire 71. The I/F circuit board 7 has an interface function between the sensor unit 1 and another sensor or circuit unit. The I/F circuit board 7 is attached to the lid 3, for example, with an adhesive, screw or the like.

The lid 3 has a recessed shape having a recess 31 opening at the lower side. The lid 3 is fixed to the base 2, with the recess 31 accommodating the sensor module 5, the control circuit board 6, and the I/F circuit board 7. Thus, the lid 3 can protect the sensor module 5, the control circuit board 6, and the I/F circuit board 7. The fixing of the lid 3 to the base 2 is not limited to any particular method. In this embodiment, the lid 3 is fixed to the base 2 with a screw. A seal member 30 is provided between the lid 3 and the base 2 and keeps an internal space S in the container 4 airtight or liquid-tight. Thus, the sensor module 5, the control circuit board 6, and the I/F circuit board 7 accommodated in the internal space S are protected from moisture.

The connectors 81 and 82 are attached to a sidewall of the lid 3. These connectors 81 and 82 have the function of electrically coupling the inside and outside of the container 4. Providing the two connectors 81 and 82 enables a plurality of sensor units 1 to be coupled in series. Particularly, in this embodiment, the connectors 81 and 82 are provided at two sidewalls opposite each other along the X-axis, of the sidewalls of the lid 3. As described above, the base 2 has its longitudinal side along the X-axis. Therefore, the connectors 81 and 82, arranged in this way, overlap the base 2 and do not extend beyond the base 2, as viewed in a plan view from a direction along the Z-axis. Thus, the sensor unit 1 can be miniaturized and the connectors 81 and 82 can be protected.

Such a lid 3 is formed of, for example, aluminum. This makes the lid 3 sufficiently hard. However, the material forming the lid 3 is not particularly limited to aluminum. Other metal materials such as zinc and stainless steel, various ceramics, various resin materials, a composite material of a metal material and a resin material, or the like, can be used.

The sensor unit 1 has been described above. Such a sensor unit 1 has: the sensor module 5 having the angular velocity sensors 54x, 54y and 54z and the acceleration sensor 55 installed therein as inertial sensors and having the bottom wall 51A and the sidewall 51C; the base 2, where the sensor module 5 is provided; the first bonding member 91 bonding the base 2 and the sidewall 51C together; and the second bonding member 92 bonding the base 2 and the bottom wall 51A together. The sensor module 5 is a polygon as viewed in a plan view of the bottom wall 51A, that is, in a plan view from a direction along the Z-axis. The base 2 and the sidewall 51C are bonded together via the first bonding member 91 at a part of at least one of the sides 511 to 516 except the corners of the polygon. Such a configuration can reduce, for example, the sensitivity to noise vibration and thus can effectively restrain a drop in the inertial detection property of the sensor unit 1. In this embodiment, the base 2 and the sidewall 51C are bonded together at all the sides 511 to 516. However, this is not limiting. The base 2 and the sidewall 51C may be bonded together at a part where at least one of the sides 511 to 516 is present.

As described above, the acceleration sensor 55 as an inertial sensor has a sensitivity in a direction along the bottom wall 51A, that is, in a planar direction including the X-axis and the Y-axis. In this embodiment, the acceleration sensor 55 has a sensitivity along the X-axis and the Y-axis and can detect an acceleration along the X-axis and an acceleration along the Y-axis. As can be understood from FIGS. 12 and 13, particularly the noise sensitivity can be reduced along the X-axis and the Y-axis and therefore an acceleration along the X-axis and an acceleration along the Y-axis can be detected more accurately. That is, the sensor unit 1 can achieve its effect more prominently by being combined with an inertial sensor having a sensitivity along the X-axis and the Y-axis.

As described above, the base 2 has the closed-bottom recess 22, in which the sensor module 5 is inserted. The lateral surface 222 of the recess 2 and the sidewall 51C are bonded together via the first bonding member 91, and the bottom surface 221 of the recess 2 and the bottom wall 51A are bonded together via the second bonding member 92. Bonding the sensor module 5 and the base 2 together via the first and second bonding members 91 and 92 in this way can sufficiently increase the bonding strength between these components.

As described above, each of the first bonding member 91 and the second bonding member 92 has a lower elastic modulus than the base 2. Therefore, the first and second bonding members 91 and 92 can effectively absorb and damp noise vibration transmitted from the base 2 and make the noise vibration less likely to be transmitted to the sensor module 5. Thus, a drop in detection property can be restrained more effectively.

As described above, the first bonding member 91 and the second bonding member 92 have different elastic moduli from each other. This enables the first bonding member 91 and the second bonding member 92 to effectively absorb and damp different frequency ranges of noise vibration from each other and therefore enables the first and second bonding members 91 and 92 together to absorb and damp a broader frequency range of noise vibration.

As described above, the sensor unit 1 has the lid 3 covering the sensor module 5 and bonded to the base 2. Thus, the sensor module 5 can be protected.

### Second Embodiment

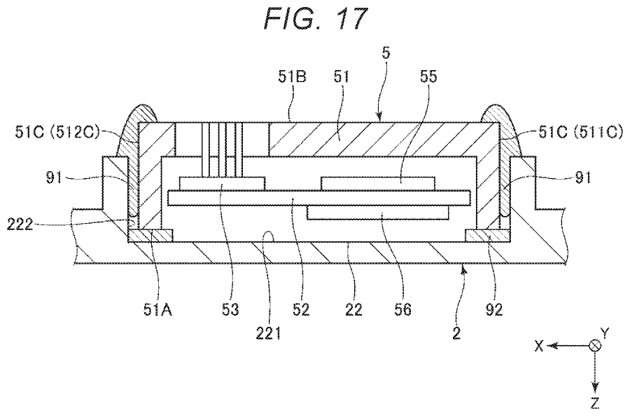

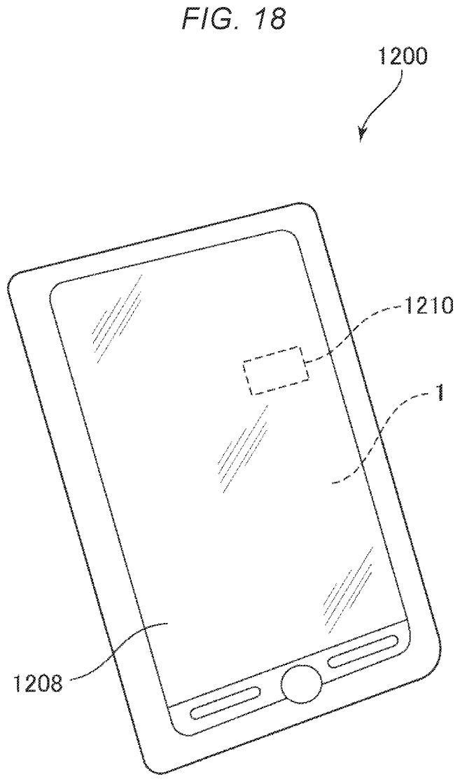

FIG. 17 is a cross-sectional view showing a sensor module according to a second embodiment.

The sensor module 5 according to this embodiment is similar to that in the sensor unit 1 according to the first embodiment except that the configuration of the first bonding member 91 is different. In the description below, the sensor unit 1 according to the second embodiment is described mainly in terms of the difference from the first embodiment and the description of similar matters is omitted. In FIG. 17, components similar to those in the foregoing embodiment are denoted by the same reference signs.

As shown in FIG. 17, the first bonding member 91 is located between the sidewall 51C of the sensor module 5 and the lateral surface 222 of the recess 22 and bonds the sidewall 51C and the lateral surface 222 together. The first bonding member 91 also spreads over the top wall 51B of the case 51 and the upper surface of the base 2 and bonds the top wall 51B and the sidewall 51C to the base 2. Thus, the contact area between the first bonding member 91 and the sensor module 5 is larger than in the first embodiment and therefore the bonding strength between the sensor module 5 and the base 2 becomes high. This can increase the mechanical strength of the sensor unit 1.

As described above, in the sensor unit 1 according to this embodiment, the sensor module 5 has the top wall 51B located at the side opposite to the bottom wall 51A, and the first bonding member 91 bonds the sidewall 51C and the top wall 51B to the base 2. Thus, the contact area between the first bonding member 91 and the sensor module 5 is larger than in the first embodiment and therefore the bonding strength between the sensor module 5 and the base 2 becomes high. This can increase the mechanical strength of the sensor unit 1.

### Third Embodiment

FIG. 18 is a perspective view showing a smartphone according to a third embodiment.

A smartphone 1200 as an electronic apparatus shown in FIG. 18 has the sensor unit 1 and a control circuit 1210 performing control based on a detection signal outputted from the sensor unit 1, as built-in components. Detection data detected by the sensor unit 1 is transmitted to the control circuit 1210. The control circuit 1210 recognizes the attitude and behavior of the smartphone 1200, based on the received detection data, and can change the display image displayed at a display unit 1208, output an alarm sound or sound effect, or drive a vibration motor to vibrate the main body.

Such a smartphone 1200 as an electronic apparatus has the sensor unit 1 and the control circuit 1210 performing control based on a detection signal from the sensor unit 1. Therefore, the smartphone 1200 can have the effect of the sensor unit 1 and achieve high reliability.

The electronic apparatus can also be applied to, for example, a personal computer, digital still camera, tablet terminal, timepiece, smart watch, inkjet printer, laptop personal computer, television, wearable terminal such as HMD (head-mounted display), video camera, video tape recorder, car navigation device, pager, electronic organizer, electronic dictionary, electronic calculator, electronic game device, word processor, workstation, videophone, security monitor, electronic binoculars, POS terminal, medical equipment, fishfinder, various measuring devices, device for mobile terminal base station, instruments of vehicle, aircraft or ship, flight simulator, network server or the like, as well as the smartphone 1200.

### Fourth Embodiment

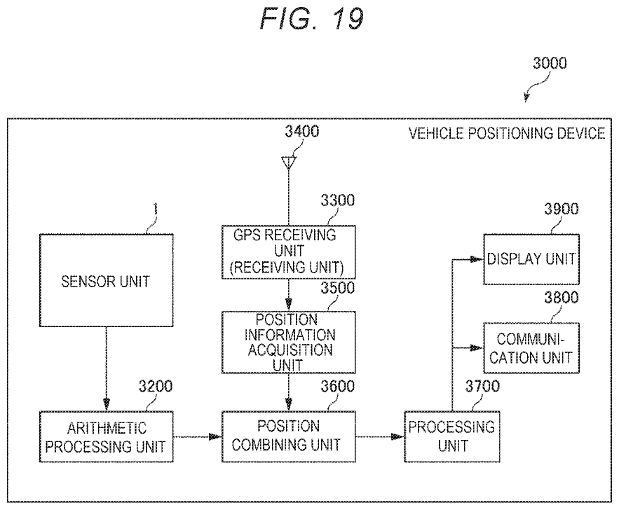

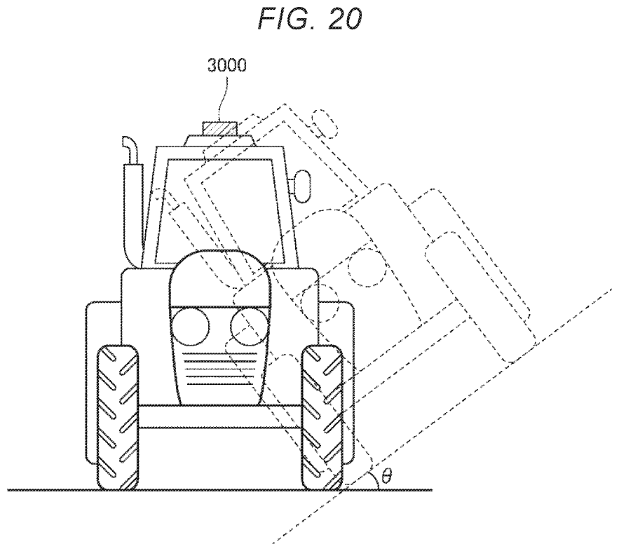

FIG. 19 is a block diagram showing an overall system of a vehicle positioning device according to a fourth embodiment. FIG. 20 shows an operation of the vehicle positioning device shown in FIG. 19.

A vehicle positioning device 3000 shown in FIG. 19 is a device used in the state of being loaded in a vehicle and configured to measure the position of the vehicle. The vehicle is not particularly limited and may be any of bicycle, automobile, motorcycle, electric train, aircraft, ship and the like. In this embodiment, the case where a four-wheel automobile is used as the vehicle is described.

The vehicle positioning device 3000 has the sensor unit 1, an arithmetic processing unit 3200, a GPS receiving unit 3300, a receiving antenna 3400, a position information acquisition unit 3500, a position combining unit 3600, a processing unit 3700, a communication unit 3800, and a display unit 3900.

The arithmetic processing unit 3200 receives acceleration data and angular velocity data from the sensor unit 1, performs inertial navigation processing on these data, and outputs inertial navigation positioning data including the acceleration and attitude of the vehicle. The GPS receiving unit 3300 receives a signal from a GPS satellite via the receiving antenna 3400. The position information acquisition unit 3500 outputs GPS positioning data representing the position (latitude, longitude, altitude), velocity, and compass direction of the vehicle positioning device 3000, based on the signal received by the GPS receiving unit 3300. The GPS positioning data includes status data representing the reception status, time of reception, and the like.

The position combining unit 3600 calculates the position of the vehicle, specifically, at which position on the ground the vehicle is travelling, based on the inertial navigation positioning data outputted from the arithmetic processing unit 3200 and the GPS positioning data outputted from the position information acquisition unit 3500. For example, when the position of the vehicle included in the GPS positioning data is the same but the attitude of the vehicle is different due to the influence of a slope θ or the like of the ground, as shown in FIG. 20, it is understood that the vehicle is travelling at a different position on the ground. Therefore, the accurate position of the vehicle cannot be calculated solely based on the GPS positioning data. Thus, the position combining unit 3600 calculates at which position on the ground the vehicle is travelling, using the inertial navigation positioning data.

The position data outputted from the position combining unit 3600 is processed in a predetermined manner by the processing unit 3700 and displays as the result of positioning at the display unit 3900. The position data may also be transmitted from the communication unit 3800 to an external device.

### Fifth Embodiment

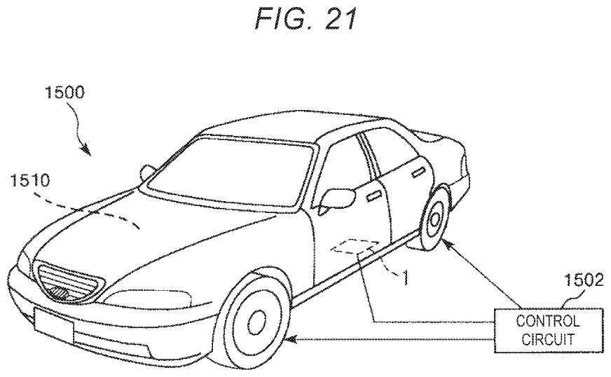

FIG. 21 is a perspective view showing a vehicle according to a fifth embodiment.

An automobile 1500 as a vehicle shown in FIG. 21 has a system 1510 that is at least one of an engine system, a brake system, and a keyless entry system, the sensor unit 1, and a control circuit 1502, as built-in components. The sensor unit 1 can detect the attitude of the vehicle body. A detection signal from the sensor unit 1 is supplied to the control circuit 1502. The control circuit 1502 can control the system 1510, based on the signal.

In this way, the automobile 1500 as a vehicle has the sensor unit 1 and the control circuit 1502 performing control based on a detection signal outputted from the sensor unit 1. Therefore, the automobile 1500 can have the effect of the sensor unit 1 and achieve high reliability.

The sensor unit 1 can also be applied broadly to an electronic control unit (ECU) such as a car navigation system, car air-conditioning, anti-lock braking system (ABS), airbags, tire pressure monitoring system (TPMS), engine control, and battery monitor for hybrid car or electric vehicle. The vehicle is not limited to the automobile 1500 and can also be applied, for example, to an aircraft, rocket, artificial satellite, ship, AGV (automated guided vehicle), bipedal walking robot, unmanned aerial vehicle such as drone, and the like.

The sensor unit, the electronic apparatus, and the vehicle according to the present disclosure have been described above, based on the illustrated embodiments. However, the present disclosure is not limited to these embodiments. The configuration of each part can be replaced by any configuration having a similar function. Also, any other arbitrary component may be added to the present disclosure. Moreover, the embodiments may be combined together according to need.

What is claimed is:

1. A sensor unit comprising:
a sensor module having an inertial sensor installed therein and having a bottom wall and a sidewall;
a base where the sensor module is provided;
a first bonding member bonding the base and the sidewall together; and
a second bonding member bonding the base and the bottom wall together, wherein
the sensor module is a polygon as viewed in a plan view of the bottom wall, and the base and the sidewall are bonded together via the first bonding member at a part of at least one side of the polygon except corners.

2. The sensor unit according to claim 1, wherein
the inertial sensor has a sensitivity in a direction along the bottom wall.

3. The sensor unit according to claim 1, wherein
the sensor module has a top wall located at a side opposite to the bottom wall, and
the first bonding member bonds the sidewall and the top wall to the base.

4. The sensor unit according to claim 1, wherein
the base has a closed-bottom recess in which the sensor module is inserted,
a lateral surface of the recess and the sidewall are bonded together via the first bonding member, and
a bottom surface of the recess and the bottom wall are bonded together via the second bonding member.

5. The sensor unit according to claim 1, wherein
the first bonding member and the second bonding member respectively have a lower elastic modulus than the base.

6. The sensor unit according to claim 5, wherein
the first bonding member and the second bonding member have different elastic moduli from each other.

7. The sensor unit according to claim 1, further comprising
a lid covering the sensor module and bonded to the base.

8. An electronic apparatus comprising:
the sensor unit according to claim 1; and
a control circuit performing control based on a detection signal outputted from the sensor unit.

9. A vehicle comprising:
the sensor unit according to claim 1; and
a control circuit performing control based on a detection signal outputted from the sensor unit.
